(19) United States
(12) Patent Application Publication
(10) Pub. No.: US 2012/0267229 A1
(43) Pub. Date: Oct. 25, 2012

(54) TOUCH PANEL AND MANUFACTURING METHOD THEREOF

(75) Inventor: JAOCHING LIN, TAIPEI CITY (TW)

(73) Assignee: HOWAY CORP., KAOHSIUNG CITY (TW)

(21) Appl. No.: 13/430,896

(22) Filed: Mar. 27, 2012

(30) Foreign Application Priority Data
Apr. 20, 2011 (TW) 100113685

(51) Int. Cl. H03K 17/975; B32B 37/14; B29C 45/14

(52) U.S. Cl. 200/600; 264/259; 264/135; 156/60

(57) ABSTRACT

A method of manufacturing a touch panel includes two steps wherein, in a first step a transparent conductive film having a front side formed with a conductive electrode pattern is prepared, and in a second step in-mold decorating (ID) techniques are applied to form a cover lens on the front side of the transparent conductive film such that the conductive electrode pattern is bonded to the cover lens when the cover lens is formed.

### CROSS-REFERENCE TO RELATED APPLICATION

This application claims priority of Taiwanese Application No. 100113685, filed on Apr. 20, 2011.

### BACKGROUND OF THE INVENTION

1. Field of the Invention

The invention relates to a touch panel, more particularly to a capacitive touch panel, and a method of manufacturing the same.

2. Description of the Related Art

Referring to FIGS. 1 and 2, a conventional method of manufacturing a capacitive touch panel 1 involves applying a conductive film 10 made of indium tin oxide (ITO) onto a substrate 11 made of amaterial, for example, polyethylene terephthalate (PET), glass or polymethyl methacrylate (PMMA). A desired conductive electrode pattern 12 is then formed on the conductive film 10 through etching. A cover lens 14 is subsequently bonded onto the substrate 11 with an optical adhesive 13, thereby disposing the conductive film 10 between the substrate 11 and the cover lens 14. A shield pattern 15 made of black ink is formed on a peripheral portion of one side of the cover lens 14 for covering a wiring portion 16 that extends from the conductive film 10 to the peripheral portion of the substrate 11. In general, the shield pattern 15 is simultaneously formed on the cover lens 14 while the cover lens 14 is formed using in-mold decoration (IMD) process. However, in the aforesaid method, the cover lens 14 is firstly formed in a mold using IMD process and then is removed from the mold and bonded to the substrate 11 using the optical adhesive 13. The method is complicated and time-consuming. Moreover, in the conventional method, the optical adhesive 13 is required.

### SUMMARY OF THE INVENTION

Therefore, the object of the present invention is to provide a touch panel that can be manufactured at a lower cost compared to conventional touch panels and to a manufacturing method thereof.

Accordingly, a method of manufacturing a touch panel of the present invention comprises two steps. The first step is preparing a transparent conductive film having a front side formed with a conductive electrode pattern. The second step is applying the in-mold decorating (IMD) techniques to form a cover lens on the front side of the transparent conductive film such that the conductive electrode pattern is bonded to the cover lens when the cover lens is formed.

### BRIEF DESCRIPTION OF THE DRAWINGS

Other features and advantages of the present invention will become apparent in the following detailed description of the preferred embodiments with reference to the accompanying drawings, of which:

FIG. 1 is a sectional view of a conventional capacitive touch panel;

FIG. 2 is a perspective view of the conventional capacitive touch panel shown in FIG. 1;

FIG. 3 is a flow chart of the first embodiment of a method of manufacturing a touch panel of this invention;

FIG. 4 illustrates consecutive steps of the first preferred embodiment;

FIG. 5 is a perspective view of a conductive electrode pattern on a first transparent conductive film prepared by a step of the first preferred embodiment;

FIG. 6 is a perspective view of a touch panel manufactured by the method shown in FIG. 3, which includes a cover lens formed on the transparent conductive film;

FIG. 7 is a flow chart of the second embodiment of a method of manufacturing a touch panel of this invention;

FIG. 8 is a schematic view of a first transparent conductive film used in the second preferred embodiment;

FIG. 9 is a schematic view of a second transparent conductive film used in the second preferred embodiment; and

FIG. 10 is a perspective view of a second preferred embodiment illustrating a touch panel manufactured by the method shown in FIG. 7.

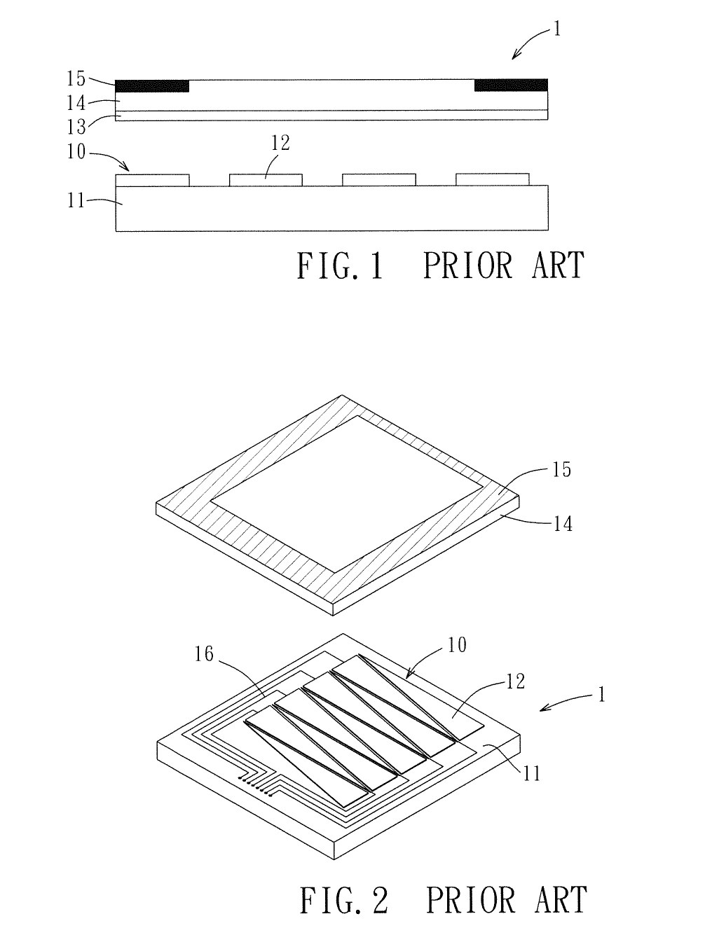

### DETAILED DESCRIPTION OF THE PREFERRED EMBODIMENTS

Before the present invention is described in greater detail, it should be noted that like elements are denoted by the same reference numerals throughout the disclosure.

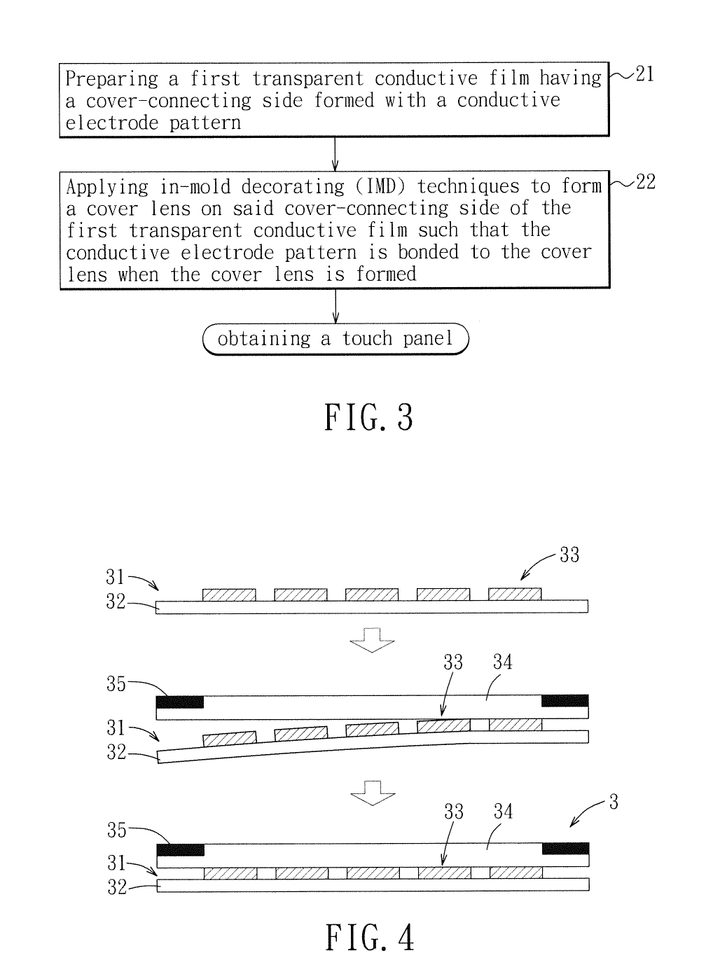

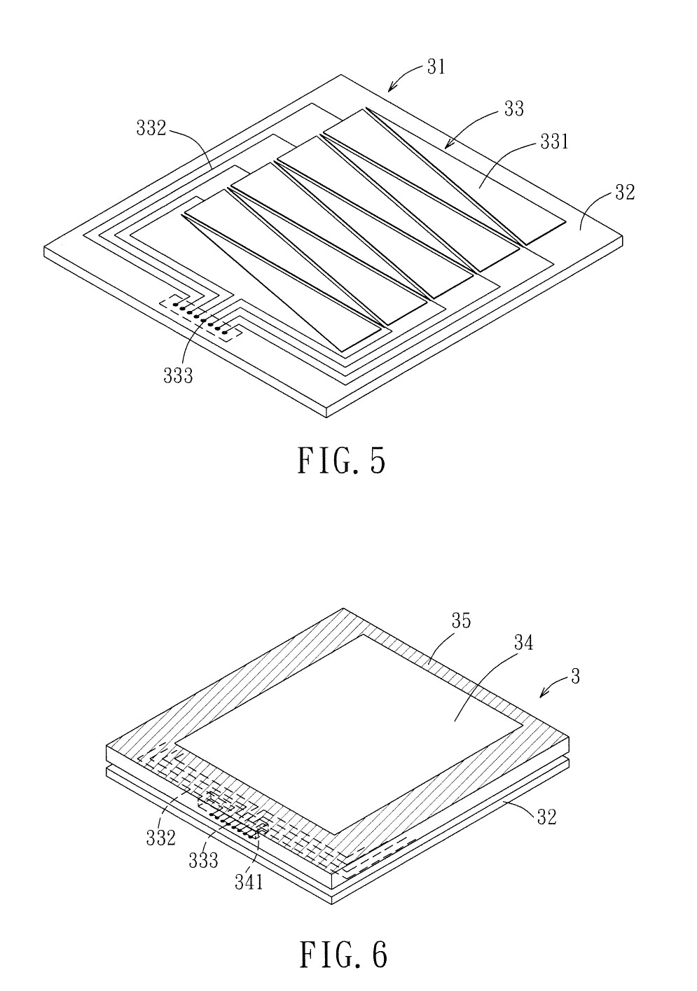

FIGS. 3 and 4 illustrate the first preferred embodiment of a method of manufacturing a touch panel according to the present invention. First, as described in step 21 of FIG. 3, a transparent conductive film 31 is prepared. The transparent conductive film 31 includes a light-transmissive film 32. The light-transmissive film 32 has a front side formed with a conductive electrode pattern 33. The light-transmissive film 32 can be made of a material selected from thermoplastic polymer or ester such as PET or PMMA. The conductive electrode pattern 33 can be a one-dimension conductive electrode structure with a plurality of electrodes 331 (as shown in FIG. 5), or other existing structures that are familiar to those skilled in the art. The conductive electrode pattern 33 can be formed on the front side of the light-transmissive film 32 by means of physical vapor deposition(PVD) or chemical vapor deposition(CVD) such as sputtering or evaporation deposition, or other ways familiar to those skilled in art.

Subsequently, as described in step 22 of FIG. 3, IMD techniques are then applied to form a cover lens 34 on the front side of the transparent conductive film 31 such that the conductive electrode pattern 33 is bonded to the cover lens 34 when the cover lens 34 is formed, thereby disposing the conductive electrode pattern 33 between the light-transmissive film 32 and the cover lens 34. Details of step 22 will be described in the succeeding paragraphs.

IMD includes three main techniques, namely In-Mold Transfer/In-Mold Roller (IMR), In-Mold Film (IMF) and In-Mold Label (IML), wherein the IMR technique is preferred in the first preferred embodiment. The transparent conductive film 31, which is flexible prior to formation of the cover lens 34 on the transparent conductive film 31, is prepared in a roller shape, and then disposed in an inner chamber of a mold by a feeder (not shown in the Figures). As shown in FIG. 4, when the cover lens 34 is being formed inside the mold by injection molding, the conductive electrode pattern 33 of the transparent conductive film 31 is bonded to a surface of the cover lens 34. That is, the light-transmissive film 32 on the conductive electrode pattern 33 serves as a protective film, thereby providing high wear-resistance. Thus, the transparent conductive film 31 and the cover lens 34 are bonded integrally without using an optical adhesive.

As shown in FIG. 4, the touch panel 3 manufactured by the first preferred embodiment comprises a transparent conductive film 31 having a light-transmissive film 32 and a conductive electrode pattern 33 formed on a front side of the light-transmissive film 32, and a cover lens 34 formed on the front side of the transparent conductive film 31. To be specific, the cover lens 34 is formed on the conductive electrode pattern 33 oppositely of the light-transmissive film 32. The IMD techniques are applied such that the conductive electrode pattern 33 is bonded directly to and covered by the cover lens 34 when the cover lens 34 is formed. Moreover, the cover lens 34 is made of a transparent material, e.g., PET, PMMA or glass.

Referring to FIGS. 5 and 6, a shield pattern 35 made of black ink is formed on the cover lens 34 for covering a wiring portion 332 that is to be formed to extend from the conductive electrode pattern 33 to the peripheral portion of one side of the cover lens 34 and a plurality of pins 333 to be formed in the cover lens 34. More specifically, the shield pattern 35 is formed at a peripheral portion of one side of the cover lens 34 simultaneously with formation of the cover lens 34 using double-injection molding techniques. A mold configured to be capable of forming the touch panel 3 is prepared in advance.

The mold can be optionally formed a connecting port structure such that a connecting port, e.g., a recess 341 or a plurality of vias (not shown in the drawings) corresponding to the pins 333, is formed simultaneously with the formation of the cover lens 34 for disposing at least one of a connecting component (e.g., a bus) and a control component (e.g., a control chip). In fact, in the first preferred embodiment, the IMF and IML techniques that are familiar to those skilled in the art, are applicable to manufacture the touch panel 3. When these techniques are utilized, the prepared transparent conductive film 31 is first placed in an inner chamber of a mold, prior to the formation of the cover lens 34. A material for the cover lens 34 is heated and injected into the mold, such that the cover lens 34 is formed on the transparent conductive film 31. Afterwards, the cover lens 34 cools down and hardens, thereby directly bonding the transparent conductive film 31 to the cover lens 34. The shield pattern 35 may be formed at a peripheral portion of one side of the cover lens 34 simultaneous with the formation of the cover lens 34 using the previously mentioned double-injection molding techniques as well.

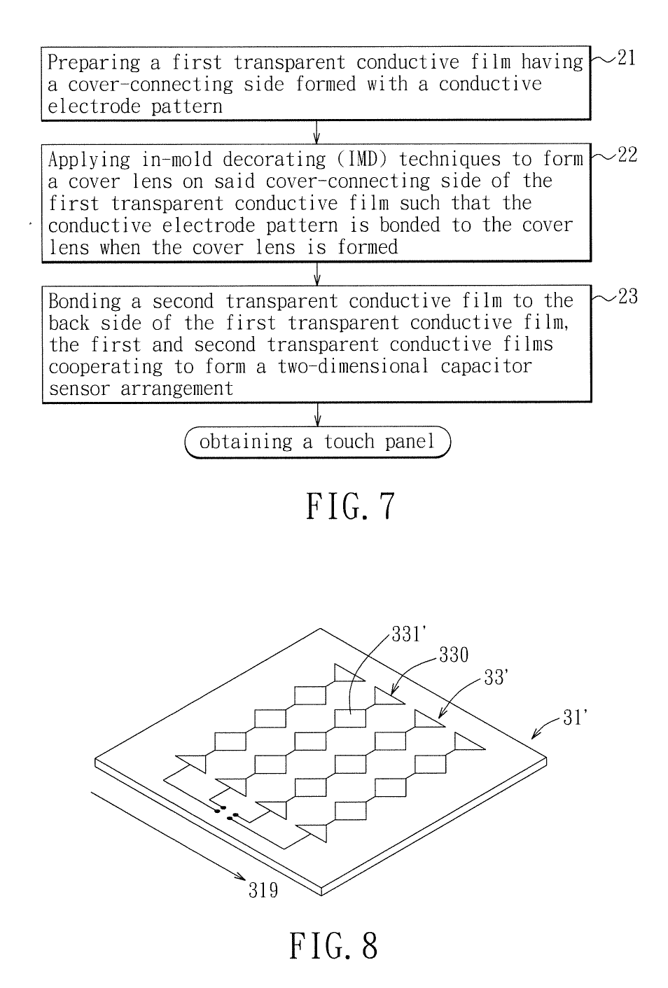

FIG. 7 illustrates the second preferred embodiment of a method of manufacturing a touch panel according to the present invention. The main differences between this embodiment and the previous embodiment reside in the configuration of a first conductive electrode pattern 33′ formed on a front side of a first transparent conductive film 31′ in step 21, and an additional step 23 included in the second preferred embodiment. To be specific, in step 21, the first conductive electrode pattern 33′ includes a plurality of first electrode rows 330 aligned along a first direction 319 (as shown in FIG. 8). Each of the first electrode rows 330 includes a plurality of conductive electrode 331′ that are connected in series.

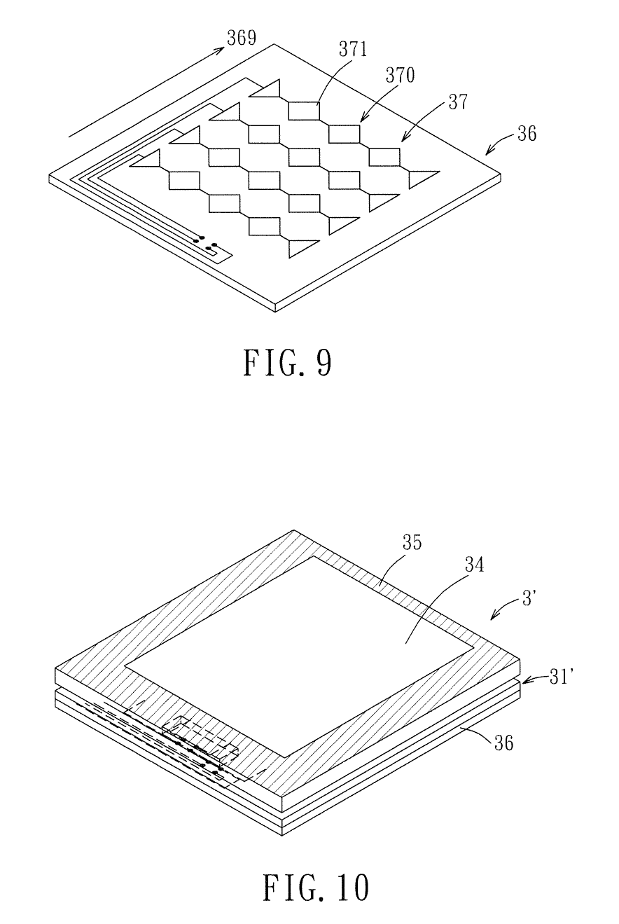

Further referring to FIG. 7, in the second embodiment, after the first conductive electrode pattern 33′ is bonded to the cover lens 34, the additional step 3, which is bonding a second transparent conductive film 36 to a back side of the light-transmissive film 32 opposite to the front side, is performed. The second transparent conductive film 36 has a film-connecting side that is formed with a second conductive electrode pattern 37 and that is connected to the back side of the light-transmissive film 32. The second conductive electrode pattern 37 includes a plurality of second electrode rows 370 that are aligned along a second direction 369 perpendicular to the first direction 319, and that are staggered spatially relative to the first electrode rows 330(as shown in FIG. 9). Each of the second electrode rows 370 includes a plurality of conductive electrode 371′ connected in series. Thus, the first and second transparent conductive films 31′ and 36 cooperate to form a two-dimensional capacitor sensor arrangement. A touch panel 3′ manufactured by the second preferred embodiment is shown in FIG. 10, which has the same advantages as those of the first preferred embodiment.

To sum up, by applying IMD techniques to form the cover lens 34 on the front side of the transparent conductive film 31 in the mold such that the conductive electrode pattern 33 is bonded to the cover lens 34 when the cover lens 34 is formed, and by applying double injection molding to form the shield pattern 35 at the peripheral portion of one side of the cover lens 34 simultaneously with formation of the cover lens 34, the capacitive touch panel 3 can be manufactured at relatively lower manufacturing costs.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A method of manufacturing a touch panel comprising:
providing a first transparent conductive film having a front side formed with a conductive electrode pattern; and
applying in-mold decorating (IMD) techniques to form a cover lens on said front side of the first transparent conductive film such that the conductive electrode pattern is bonded to the cover lens when the cover lens is formed.

2. The method as claimed in claim 1, wherein, in step a), the first transparent conductive film includes a light-transmissive film on which the conductive electrode pattern is formed by deposition techniques.

3. The method as claimed in claim 2, wherein the light-transmissive film is made of a material selected from thermoplastic material and ester.

4. The method as claimed in claim 1, wherein, in step b), the IMD techniques are selected from the group consisting of in-mold transfer (IMT), in-mold roller (IMR), in-mold film (IMF) and in-mold label (IML) techniques.

5. The method as claimed in claim 1, wherein, in step b) , a shield pattern is formed at a peripheral portion of one side of the cover lens simultaneous with formation of the cover lens using double-injection molding techniques.

6. The method as claimed in claim 1, wherein the cover lens is made of a material selected from PET, PMMA and glass.

7. The method as claimed in claim 1, wherein, in step b) , the cover lens is formed with a connecting port for disposing a connecting component.

8. The method as claimed in claim 1, wherein, in step b) , the cover lens is formed with a connecting port for disposing a control component.

9. The method as claimed in claim 1, wherein the first transparent conductive film further has a back side opposite to the front side, said method further comprising:
(c) bonding a second transparent conductive film to the back side of the first transparent conductive film, the first and second transparent conductive films cooperating to form a two-dimensional capacitor sensor arrangement.

10. A touch panel comprising:
a first transparent conductive filmhaving a front side formed with a conductive electrode pattern; and
a cover lens formed on said front side of said first transparent conductive film using in-mold decorating (IMD) techniques such that said conductive electrode pattern is bonded directly to and covered by said cover lens when said cover lens is formed.

11. The touch panel as claimed in claim 10, wherein said first transparent conductive film includes a light-transmissive film on which said conductive electrode pattern is formed by deposition techniques.

12. The touch panel as claimed in claim 10, wherein the IMD techniques are selected from the group consisting of in-mold transfer (IMT), in-mold roller (IMR), in-mold film (IMF) and in-mold label (IML) techniques.

13. The touch panel as claimed in claim 10, further comprising a shield pattern formed at a peripheral portion of one side of said cover lens.

14. The touch panel as claimed in claim 10, wherein said cover lens is made of a material selected from PET, PMMA and glass.

15. The touch panel as claimed in claim 10, wherein said cover lens is formed with a connecting port for disposing a connecting component.

16. The touch panel as claimed in claim 10, wherein said cover lens is formed with a connecting port for disposing a control component.

17. The touch panel as claimed in claim 10, wherein said first transparent conductive film further has a back side opposite to said front side, said touchpanel further comprising a second transparent conductive film bonded to said back side of said first transparent conductive film, said first and second transparent conductive films cooperating to form a two-dimensional capacitor sensor arrangement.
